(19) United States
(12) Patent Application Publication
(10) Pub. No.: US 2022/0246510 A1
(43) Pub. Date: Aug. 4, 2022

(54) OPEN WEB ELECTRICAL SUPPORT FOR CONTACT PAD AND METHOD OF MANUFACTURE

(71) Applicant: HYPERTAC S.P.A., Genova (IT)

(72) Inventors: Alessandro Bosca, Genova (IT); Jedidiah Bentz, Genova (IT); Vishal Musaramthota, Genova (IT); Scott R. Kempshall, Genova (IT); Dave Henry, Genova (IT); Agnese Denzi, Genova (IT)

(21) Appl. No.: 17/623,769

(22) PCT Filed: Jul. 3, 2020
(86) PCT No.: PCT/EP2020/068830

§ 371 Date: Dec. 29, 2021

(30) Foreign Application Priority Data
Jul. 4, 2019 (EP) 19425049.4

(51) Int. Cl. H01L 23/498; H01L 23/00; H01R 12/71; H01R 12/79; H01L 21/48; H01R 43/00; H01R 13/24

(52) U.S. Cl. CPC H01L 23/49827; H01L 2224/29466; H01R 12/714; H01R 12/79; H01L 21/486; H01L 24/27; H01R 43/00; H01R 13/2407; H01L 2224/29393; H01L 2224/29499; H01L 2224/29339; H01L 2224/29384; H01L 2224/29355; H01L 2224/29347; H01L 2224/29344; H01L 2224/29318; H01L 2224/29369; H01L 2224/29311; H01L 2224/29338; H01L 2924/01014; H01L 2924/0523; H01L 2924/0503; H01L 2224/29386; H01L 2924/0549; H01L 2224/2712; H01L 2224/29416; H01L 2224/29469; H01L 2224/29444; H01L 24/29

(57) ABSTRACT

In some aspects, it is disclosed an electrical support for at least one electrical contact pad, including an insulating viscoelastic matrix, and at least one elastically deformable structure made of a conductive material to form an open web, the at least one structure including at least a core part which is embedded within the insulating matrix, and at least one connection part which extends out of the insulating matrix and is configured to be connected to the at least one electrical contact pad, wherein the structure includes a stiffer section corresponding substantially to the core part of the structure and at least one more flexible section corresponding substantially to the at least one connection part of the structure.

### CROSS-REFERENCE TO RELATED APPLICATIONS

This patent application is a National Stage Entry of PCT/EP2020/068830 filed on Jul. 3, 2020, which claims priority to EP Application No. 19425049.4 filed on Jul. 4, 2019, the disclosures of which are hereby incorporated by reference herein in their entirety as part of the present application.

### FIELD OF DISCLOSURE

The disclosure relates, but is not limited to, an electrical support for at least one electrical contact pad. The disclosure also relates to a method of manufacture of such a support.

### BACKGROUND

Known electrical supports enable electrical conduction to or from at least one electrical contact pad, such as a contact pad for a chip. Some supports may be used as interposers between printed circuit boards, PCB.

### SUMMARY

Aspects and embodiments of the disclosure are set out in the appended claims. These and other aspects and embodiments of the disclosure are also described herein.

In one aspect, an electrical support for at least one electrical contact pad is provided. The electrical support includes an insulating viscoelastic matrix, and at least one elastically deformable structure made of a conductive material to form an open web, the at least one structure including at least a core part which is embedded within the insulating matrix, and at least one connection part which extends out of the insulating matrix and is configured to be connected to the at least one electrical contact pad, wherein the structure includes a stiffer section corresponding substantially to the core part of the structure and at least one more flexible section corresponding substantially to the at least one connection part of the structure.

In another aspect, a method of manufacturing an electrical support for at least one electrical contact pad is provided. The method includes manufacturing at least one elastically deformable, open web structure made of a conductive material, and manufacturing an insulating viscoelastic matrix, such that the at least one structure includes at least a core part which is embedded within the insulating matrix, and at least one connection part which extends out of the insulating matrix and is configured to be connected to the electrical contact pad, wherein the structure includes a stiffer section corresponding substantially to the core part of the structure and at least one more flexible section corresponding substantially to the at least one connection part of the structure.

### BRIEF DESCRIPTION OF THE DRAWINGS

Aspects of the disclosure will now be described, by way of example, with reference to the accompanying drawings in which:

FIG. 1A is an elevation view, in a longitudinal cross section, which schematically illustrates an electrical support for at least one electrical contact pad according to the disclosure, not subjected to a load;

FIG. 1B is an elevation view, in a longitudinal cross section, which schematically illustrates the support of FIG. 1A subjected to a load;

FIG. 2A is an elevation view, in a longitudinal cross section, which schematically illustrates a first example electrical support according to the disclosure, not subjected to a load;

FIG. 2B is an elevation view, in a longitudinal cross section, which schematically illustrates the support of FIG. 2A subjected to a load;

FIG. 3A is an elevation view, in a longitudinal cross section, which schematically illustrates a second example electrical support according to the disclosure, not subjected to a load;

FIG. 3B is an elevation view, in a longitudinal cross section, which schematically illustrates the support of FIG. 3A subjected to a load;

FIG. 4 schematically illustrates example steps of a method of manufacture of a support of any one of the aspects of the disclosure.

In the drawings, similar elements bear identical numerical references.

### DETAILED DESCRIPTION

Overview

The disclosure relates but is not limited to an electrical support for at least one electrical contact pad. The support includes an insulating viscoelastic matrix in which is partly embedded at least one elastically deformable structure made of a conductive material. Each of the structures forms an open web, such as a foam, a network, a scaffolding or a lattice. Each structure includes a stiffer section corresponding substantially to a part of the structure which is embedded in the matrix and a more flexible section corresponding substantially to a part of the structure which is connected to the electrical contact pad, outside the matrix.

The matrix provides substantially a thickness of the support, mechanical reinforcement to the structures and chemical stability to the structures.

Each structure is conductive and the open web provides multiple points of electrical contacts to the contact pad, as well as multiple conduction paths to and from the contact pad.

Each structure is elastically deformable and the more flexible section not embedded in the matrix provides compliance with deformations under which the support undergoes when subjected to a load. However the stiffer section reinforces the structure against over compression under the load and limits wear damage to the support.

The matrix may include a hydrophobic material and may provide a stop layer and may seal the support from moisture and other contaminants.

### Detailed Description of Example Embodiments

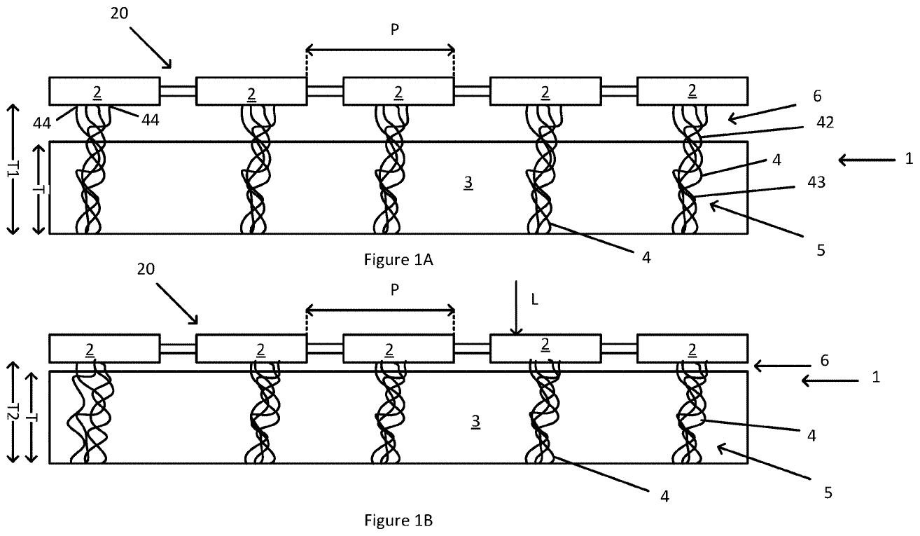

FIGS. 1A and 1B schematically illustrate an electrical support 1 for at least one electrical contact pad 2.

The support 1 includes an insulating viscoelastic matrix 3.

The support 1 also includes at least one elastically deformable structure 4 made of a conductive material.

As illustrated in FIGS. 1A and 1B, each structure 4 forms an open web. In the context of the present disclosure, an open web refers to interconnected elements leaving spaces between them, such as a foam, a network (such as a network of beams or strings), a scaffolding (such as a scaffolding of beams or strings) or a lattice (such as a lattice of beams or strings).

Each structure 4 is conductive and the open web provides multiple points 44 of electrical contacts to the contact pad 2, as well as multiple conduction paths to and from the contact pad 2.

Each structure 4 is at least partly embedded in the matrix 3. In FIG. 1A the support 1 has a thickness T1 and in FIG. 1B the support 1 has a thickness T2, however a thickness T of the matrix 3 may provide substantially a thickness of the support 1, i.e. the majority of the thicknesses T1 or T2 of the support 1 is formed from the thickness T of the matrix 3, and T is substantially constant even when the support 1 is subjected to a load L (as illustrated in FIG. 1B). In some non-limiting examples,

T≥0.5×T1, and/or

T≥0.5×T2.

The matrix 3 also provides mechanical reinforcement to the at least one structure 4 and chemical stability to the at least one structure 4. The matrix 3 enables maintaining the structural stability of the open web structure 4. The matrix 3 enables maintaining the spaces between the interconnected elements of the open web structure 4.

Each structure 4 includes at least:

a core part 5 which is embedded within the insulating matrix 3, and

at least one connection part 6 which extends out of the insulating matrix 3 and is configured to be connected to the at least one electrical contact pad 2.

Each structure 4 includes a stiffer section 43 corresponding substantially to the core part 5 of the structure 4. The stiffer section 43 reinforces the structure 4 against over compression under the load L applied to the support 1, as illustrated in FIG. 1B. It should be understood that, in some examples, the stiffer section 43 may extend outside the matrix 3.

Alternatively or additionally, each structure 4 also includes at least one more flexible section 42 corresponding substantially to the at least one connection part 6 of the structure 4. Each structure 4 is elastically deformable, and the more flexible section 42, substantially not embedded in the matrix 3, provides compliance with deformations the support 1 undergoes when subjected to the load L, as illustrated in FIG. 1B with T2<T1. The matrix 3 enables maintaining and enhancing the elastic compliancy of the open web structure 4. It should be understood that, in some examples, the more flexible section 42 may be embedded in the matrix 3.

The at least one more flexible section 42 substantially provides the multiple points 44 of electrical contacts to the contact pad 2, as well as multiple conduction paths to and from the contact pad 2 (in combination with the stiffer section 43).

In some examples, the viscoelastic matrix 3 is made of a material including a hydrophobic elastomer. The matrix 3 may provide a stop layer and may seal the support 1 from moisture and other contaminants.

In some examples, the structure 4 includes a structure made of a carbon-based material. In such examples, the material of the carbon-based structure may include a carbon allotrope. The carbon allotrope may include at least one of:

one or more carbon nanotubes, CNT;

one or more carbon nanobuds;

one or more carbon peapods;

one or more graphenated one or more CNTs;

one or more 3D nanoarchitectures including a mix of graphene and CNTs;

a glassy carbon;

a graphene;

one or more fullerenes;

one or more graphitic foliates; and/or

a carbon nanofoam.

The CNT may be single-walled or may include a plurality of walls and diameters. Non limiting examples include at least one of double-walled carbon nanotubes (DWNTs) and/or multi-walled carbon nanotubes (MWCNTs).

As stated above, the CNTs may be hybridized with other carbon allotropes, and non limiting examples of other carbon allotropes include fullerenes, graphitic foliates, graphene, the carbon allotropes thus forming other morphologies such as carbon nanobuds, carbon peapods, graphenated CNTs, graphene and CNTs 3D nanoarchitectures. Non-limiting examples of 3D nanoarchitectures include scaffoldings, foams and networks, such as pillared graphene. CNTs may be connected by themselves and/or integrated with other carbon allotropes by junctions or cross-linking. All of the above combinations may be incorporated in glassy carbon.

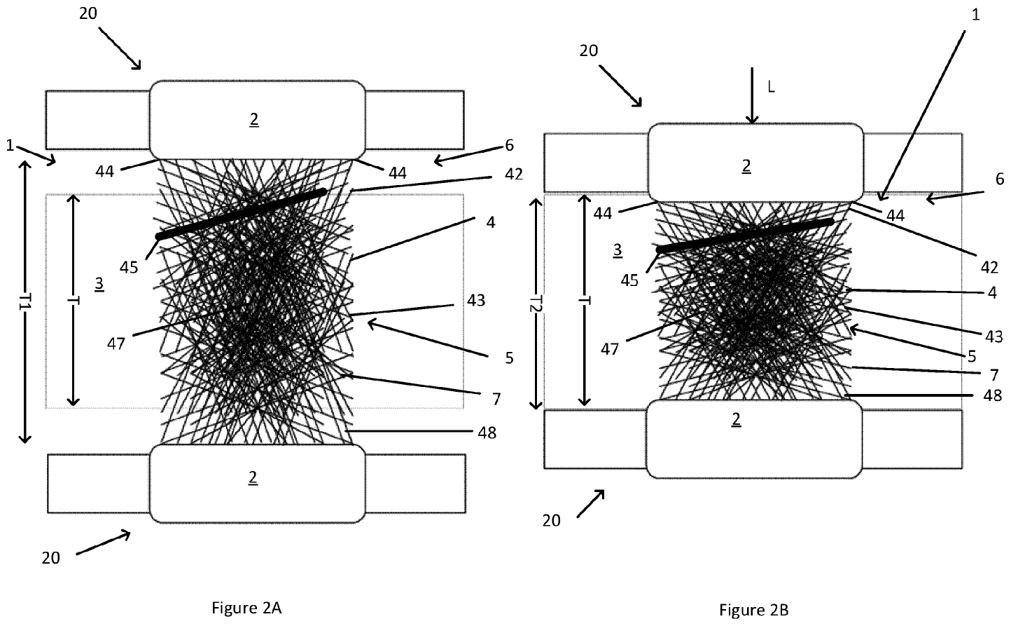

In some examples, the carbon-based structure may include a highly-ordered network of CNT. Alternatively or additionally, as illustrated in FIGS. 2A and 2B, the carbon-based structure 4 may include a random network 7 of CNT. In some examples, the random network of CNT may include CNT sponges.

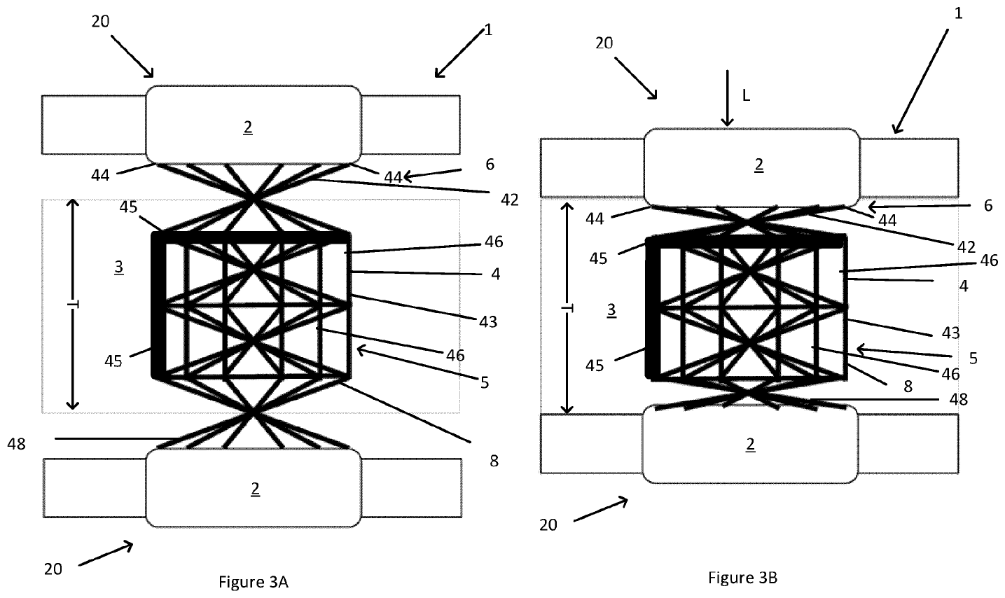

Alternatively or additionally, as illustrated in FIGS. 3A and 3B, the carbon-based structure may include a glassy carbon nanolattice 8 and/or a CNT nanolattice 8.

In some examples, the glassy carbon nanolattice 8 further includes a thin layer of metal to enhance the electrical conductivity of the nanolattice. The thin layer of metal may include a thin layer of at least one of lead, platinum, gold or titanium, but other metals are envisaged.

Alternatively or additionally, one or more types of CNTs may be chosen among different types of CNTs in order to obtain suitable mechanical and electrical properties of the one or more structures 4. The different types of CNTs include at least one of CNTs with different numbers of walls, different chiralities, different beam or string diameters and/or different surface chemistries. It should be understood that chirality may have an impact directly on electrical properties of the CNTs, but may also have an impact indirectly on a size and a stability of the CNTs. It should be understood that surface properties may have an impact on how the CNTs conduct electricity and on how the CNTs react between themselves, with other carbon allotropes and/or with the matrix. The surface properties may also contribute to the architecture topology and stability of the structure, and may contribute to integration of the structure within the surrounding matrix.

Alternatively or additionally, the structure may include a structure made of nanowires and/or nanofibers, as non-limiting examples. The nanowires and/or nanofibers may be composed of at least one of:

one or more metals (non-limiting examples include silver, tungsten, nickel, copper, gold, zinc, platinum, tin and relative alloys);

semiconductors (non-limiting examples include silicon, indium phosphide, gallium nitride or carbon); and/or

superconductors (such as yttrium barium copper oxide YBCO).

Alternatively or additionally, the structure may include a structure made of nanowires and/or nanofibers composed of insulators (non-limiting examples include SiO₂ and TiO₂). Non-conductive nanowires and/or nanofibers may be used to improve the mechanical properties of the structures.

In some examples, the stiffer section 43 may include thicker beams or strings 45 than beams or strings in the more flexible section 42 (e.g. FIGS. 2A and 2B and FIGS. 3A and 3B). Alternatively or additionally, the stiffer section 43 may include more beams or strings 46 which are substantially perpendicular to the at least one electrical contact pad 2 than the more flexible section 42 (e.g. FIGS. 3A and 3B). In some examples, the stiffer section 43 may include a higher density 47 of the web than the more flexible section 42 (e.g. FIGS. 2A and 2B). Alternatively or additionally, the stiffer section 43 may include more interconnections of the web than the more flexible section 42 (e.g. FIGS. 2A and 2B). Differences may include differences in the topology and interconnections between the carbon allotropes obtained through different cross-linkers and junctions, in order to form 3D architectures with different densities and suitable mechanical properties.

Alternatively or additionally, the stiffer section 43 may include one or more different types of CNTs compared to CNTs in the more flexible section 42. Differences may include at least one of different number of walls, chirality, diameter and/or surface chemistry as explained above.

Alternatively or additionally, the stiffer section 43 may include a different combination of carbon allotropes (CNTs, graphene and hybrids as already stated) compared to the more flexible section 42. Differences may also include differences in the topology and interconnections between the carbon allotropes obtained through different cross-linkers and junctions in order to form 3D architectures with different densities and suitable mechanical properties. Differences may also include differences in the surface properties of the carbon allotropes compared to the surface properties of the ones in the more flexible section 42. The surface properties may contribute to the architecture topology and stability of the structure as well as the proper integration of the structure with the surrounding matrix and the electrical conductivity of the structure.

Alternatively or additionally, the stiffer section may include a higher density of CNT than the more flexible section. Alternatively or additionally, the stiffer section may include a higher density of a nanolattice than the more flexible section.

As illustrated in FIGS. 2A, 2B, 3A and 3B, the support 1 may be configured to support two arrays 20 of e.g. only one pad 2. As illustrated in FIGS. 1A and 1B, the support 1 may be configured to support only one array 20.

As illustrated in FIGS. 2A, 2B, 3A and 3B, the support 1 may be configured to be an interposer between two arrays 20 of at least one electrical contact pad 2. The arrays 20 illustrated in FIGS. 2A, 2B, 3A and 3B include only one pad 2, but it should be understood that each array 20 could include a plurality of pads 2.

As illustrated in FIGS. 2A, 2B, 3A and 3B, the connection part 42 of the structure 4 may be connected to a first array 20 of the two arrays 20. The structure 4 further includes a second connection part 48 which extends out of the insulating matrix 3 and is configured to be connected to a second array 20 of the two arrays 20.

As illustrated in FIGS. 1A and 1B, the plurality of electrical contact pads 2 may be separated by a pitch P. In some examples, P may be such that:

0<P≤0.3 mm (i.e. 300 μm).

As explained in greater detail below, methods of manufacturing of the support, according to the disclosure, enable scalability of the support, such that, in some examples, the pitch P may be such that:

0<P≤0.01 mm (10 μm), or

0<P<0.001 mm (i.e. submicron pitch).

Other dimensions may be envisaged, and the pitch P may be larger than 0.3 mm (300 μm).

Alternatively or additionally, the thickness T of the insulating viscoelastic matrix 3 may be such that:

0<T≤0.3 mm (i.e. 300 μm).

As already stated, the methods of manufacturing of the support, according to the disclosure, enable scalability of the support, such that, in some examples, the thickness T may be such that:

0<T≤0.01 mm (10 μm), or

0<T<0.001 mm (i.e. submicron thickness).

Other dimensions may be envisaged, and the thickness T may be larger than 0.3 mm (300 μm).

The disclosure also relates to electrical devices including the electrical support 1 of any aspects of the disclosure and at least one electrical contact pad connected to the connection part 42 (or 48 when present) of the structure 4 of the support 1.

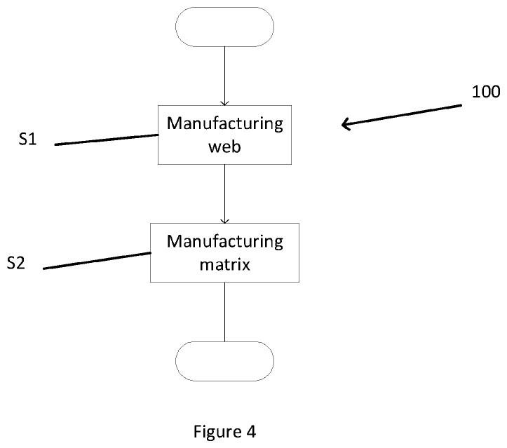

FIG. 4 schematically illustrates a method 100 of manufacturing an electrical support for at least one electrical contact pad.

The method 100 includes:

manufacturing, at 51, at least one elastically deformable, open web structure made of a conductive material; and

manufacturing, at S2, an insulating viscoelastic matrix.

At S2, the manufacturing is performed such that the structure includes at least a core part which is embedded within the insulating matrix, and at least one connection part which extends out of the insulating matrix and is configured to be connected to the electrical contact pad. At S2, the manufacturing is performed such that the structure includes a stiffer section corresponding substantially to the core part of the structure and at least one more flexible section corresponding substantially to the at least one connection part of the structure.

The method 100 may be performed to manufacture the support 1 of any aspects of the disclosure.

As already stated, the one or more structures may include one or more CNTs which may be single-walled or may include a plurality of walls and diameters. The CNTs may be hybridized with other carbon allotropes, and non-limiting examples of other carbon allotropes include fullerenes, graphitic foliates, graphene, the carbon allotropes thus forming other morphologies such as carbon nanobuds, carbon peapods, graphenated CNTs, a graphene and/or CNTs 3D nanoarchitectures. Non-limiting examples of 3D nanoarchitectures include scaffoldings, foams and networks, such as pillared graphene. CNTs may be connected by themselves and/or integrated with other carbon allotropes by junctions or cross-linking. All of the above combinations may be incorporated in glassy carbon. The one or more structure may also include a structure made of nanowires and/or nanofibers.

In some non-limiting examples, manufacturing the one or more structures at 51 may include enabling the one or more structures to self-assemble in a highly-ordered network or a random network. Alternatively or additionally, manufacturing the one or more structures at 51 may include engineering one or more initial structures by 3D lithography and obtaining one or more final structures using pyrolysis. Alternatively or additionally, manufacturing the one or more structures at 51 and the matrix at S2 may include engineering one or more initial structures by 3D lithography by embedding the one or more structures inside an insulating viscoelastic matrix and obtaining one or more structures using pyrolysis.

The method 100 enables scalability of the support to predetermined and desired dimensions. Alternatively or additionally, the method 100 enables engineering of the mechanical, chemical and/or conductive properties of the support to predetermined and desired properties.

In some examples, the manufacturing at 51 of the structure further includes depositing a thin layer of metal on the glassy carbon nanolattice to enhance the electrical conductivity of the nanolattice. The thin layer of metal may include a thin layer of at least one of lead, platinum, gold or titanium, but other metals are envisaged. In some non-limiting examples, depositing the thin layer of metal may be performed by Atomic Layer Deposition, ALD, but other methods may be envisaged.

The support of any aspects of the disclosure may be configured to be used in at least one of:

a Land Grid Array, LGA,

a board-to-board connector, such as an interposer,

a board-to-flex connector, such as an interposer,

an application-specific integrated circuit, ASIC,

a device with a pin count of up to several thousand I/O, and/or

an anisotropic conductive film for flip-chip integrated circuit, IC, assembly.

The above examples are non-limiting and other applications may be envisaged.

1. An electrical support for at least one electrical contact pad, comprising:
an insulating viscoelastic matrix; and
at least one elastically deformable structure made of a conductive material to form an open web, the at least one structure comprising at least:
a core part which is embedded within the insulating matrix, and
at least one connection part which extends out of the insulating matrix and is configured to be connected to the at least one electrical contact pad,
wherein the structure comprises a stiffer section corresponding substantially to the core part of the structure and at least one more flexible section corresponding substantially to the at least one connection part of the structure.

2. The support of claim 1, wherein the viscoelastic matrix is made of a material comprising a hydrophobic elastomer.

3. The support of claim 1, wherein the structure comprises a structure made of a carbon-based material.

4. The support of claim 3, wherein the at least one carbon allotrope comprises at least one of:
one or more carbon nanotubes, CNTs;
one or more carbon nanobuds;
one or more carbon peapods;
one or more graphenated one or more CNTs;
one or more 3D nanoarchitectures comprising a mix of graphene and at least one CNT;
a glassy carbon;
a graphene;
one or more fullerenes;
one or more graphitic foliates; and/or
a carbon nanofoam.

5. The support of claim 1, wherein the structure comprises a structure made of nanowires and/or nanofibers as composed of at least one of:
one or more metals;
semiconductors; and/or
superconductors.

6. The support of claim 1, wherein the stiffer section comprises at least one of:
thicker beams or strings than beams or strings in the more flexible section; and/or
more beams or strings which are substantially perpendicular to the at least one electrical contact pad than the more flexible section;
more interconnections of the web than the more flexible section; and/or
a higher density of the web than the more flexible section.

7. The support of claim 4, wherein the stiffer section comprises at least one of:
one or different types of CNTs compared to CNTs in the more flexible section, comprising at least one of:
a different chirality of CNTs compared to a chirality of CNTs in the more flexible section; and/or
a different number of walls for the CNT s compared to a number of walls for the CNTs in the more flexible section;
a different diameter of CNTs compared to a diameter of CNTs in the more flexible section; and/or
different surface properties of CNTs compared to surface properties of CNTs in the more flexible section;
a different combination of carbon allotropes compared to the more flexible section, including differences in the topology and interconnections between the carbon allotropes and/or differences in surface properties of carbon allotropes; and/or
a higher density of CNT than the more flexible section; and/or
a higher density of a nanolattice than the more flexible section.

8. The support of claim 1, configured to be an interposer between two arrays of at least one electrical contact pad, a first connection part of the structure being configured to be connected to a first array of the two arrays of the at least one electrical contact pad, and
wherein the structure further comprises a second connection part which extends out of the insulating matrix and is configured to be connected to a second array of the two arrays of the at least one electrical contact pad.

9. The support of claim 1, configured for at least one array comprising a plurality of electrical contact pads separated by a pitch P, wherein P is such that:
0<P≤0.3 mm
wherein the insulating viscoelastic matrix has a thickness T, wherein T is such that:
0<T≤0.3 mm

10. The support of claim 1, configured to be used in at least one of:
a Land Grid Array, LGA,
a board-to-board connector, such as an interposer,
a board-to-flex connector, such as an interposer,
an application-specific integrated circuit, ASIC,
a device with a pin count of up to several thousand I/O,
an anisotropic conductive film for flip-chip integrated circuit, IC, assembly.

11. An electrical device, comprising:
the electrical support of claim 1; and
at least one electrical contact pad connected to the connection part of the structure of the support.

12. A method of manufacturing an electrical support for at least one electrical contact pad, comprising:
manufacturing at least one elastically deformable, open web structure made of a conductive material; and
manufacturing an insulating viscoelastic matrix, such that the at least one structure comprises at least:
a core part which is embedded within the insulating matrix, and
at least one connection part which extends out of the insulating matrix and is configured to be connected to the electrical contact pad,
wherein the structure comprises a stiffer section corresponding substantially to the core part of the structure and at least one more flexible section corresponding substantially to the at least one connection part of the structure.

13. (canceled)

14. The method of claim 12, wherein manufacturing the at least one structure comprises using a least one of:
enabling one or more structures to self-assemble in a highly-ordered or random network; and/or
engineering one or more initial structures by 3D lithography and obtaining one or more final structures using pyrolysis; and/or
engineering one or more initial structures by 3D lithography by embedding the one or more initial structures inside an insulating viscoelastic matrix and obtaining one or more final structures using pyrolysis.

15. The method of claim 14, wherein the manufacturing of the at least one structure further comprises depositing a thin layer of metal to enhance the electrical conductivity.
